(19) United States
(12) Patent Application Publication
(10) Pub. No.: US 2019/0038512 A1
(43) Pub. Date: Feb. 7, 2019

(54) CHILD RESISTANT AND SENIOR FRIENDLY DISPENSING SYSTEM

(71) Applicant: Medicodose Systems SAS, Marseille (FR)

(72) Inventors: Nadir Benouali, Marseille (FR); William Arnold, Lambertville, NJ (US)

(21) Appl. No.: 16/073,588

(22) PCT Filed: Jan. 27, 2017
(86) PCT No.: PCT/IB17/50457

§ 371 Date: Jul. 27, 2018

Related U.S. Application Data
(60) Provisional application No. 62/288,911, filed on Jan. 29, 2016.

(51) Int. Cl. A61J 7/04; A61J 1/03; G01R 31/02; B65D 83/04; B65D 50/04

(52) U.S. Cl. CPC A61J 7/0436; A61J 1/035; A61J 2200/30; B65D 83/0463; B65D 50/046; G01R 31/025

(57) ABSTRACT

A child resistant and/or senior friendly dispensing system may include a housing, an insert plate for attaching multiple unitary dose containers and that can slide in and out of the housing and a locking means for locking the insert plate to the housing. The locking means may include a locking clip that can extend or retract to realize locking or releasing of the insert plate. The locking means enables a user to open the insert plate only when squeezing the locking clip inward with sufficient force with one hand and pulling the insert plate with another hand simultaneously. The housing may have one or more locking holes on the side walls and the locking clip may have one or more locking tabs positioned to mate with the locking holes. The system may have a sensor network and a circuitry to monitor the dispensing of unitary dose and output the result.

### RELATED APPLICATIONS AND CLAIM OF PRIORITY

This patent document claims priority to U.S. Provisional Patent Application No. 62/288,911 filed Jan. 29, 2016, the disclosure of which is incorporated herein by reference in full.

### BACKGROUND

This document relates to child resistant senior friendly unitary dose dispensing and monitoring system.

The objectives of the U.S. Consumer Product Safety Commission (CPSC) and the Poison Prevention Packaging Act of 1970 were to initiate a law specifying that all drugs should be dispensed in pharmaceutical packaging forms that were difficult for children to access, yet easy for elderly to use. The goal was to protect children from serious personal injury and life threatening conditions resulting from having an easy access to poisonous substances. However, many of the “child resistant” features that render the packaging difficult to open by toddlers ended up being equally difficult to many adults worldwide. In 1998, regulations were amended for the latter reason, i.e. to render the pharmaceutical packaging “senior friendly,” yet the same difficulty is still being observed today by many elders, and especially those with conditions like arthritis and other geriatric ailments. Current “child resistant” and “senior friendly” features and systems are either difficult to manipulate, for example, generating finger pains up to injuries and/or being too fragile such that they can be tore off easily, thus causing a lot of frustration to the patient. Tendencies to tear off a blister packaging or plastic container designed to displace the medication into a weekly, non-protected plastic containers are also widespread.

As such, there is a need in the art to provide “child resistant” and/or “senior friendly” packages that would improve patient compliance or adherence and clinical outcome. The present invention describes novel methods and devices to address these needs in the art.

### SUMMARY OF THE INVENTION

This document discloses embodiments for a child resistant and/or senior friendly dispensing system that includes a housing, an insert plate for attaching a plurality of unit dose containers and that can slide in and out of the housing, and a locking means for locking the insert plate to the housing. The dispensing system may also have a dispenser shell. In one embodiment, a child resistant senior friendly dispensing system includes a housing that has at least two opposite side walls and an opening side between the two opposite side walls. The system also includes an insert plate that can be stowed in the housing in a closing position and slid out of the housing through the opening side in an opening position. The system also includes at least one locking means for locking the insert plate to the housing. The locking clip can extend or retract upon exertion of sufficient tip pinch force so that the insert plate can be released from the closing position and slide out of the opening side of the housing to reach the opening position. Alternatively, and/or additionally, the housing may have at least one locking hole on one of the two opposite side walls. The locking clip may have at least one locking tab on one end of the clip that is positioned to mate with the locking hole on the housing and is capable of extending through and outside of the corresponding locking hole when the insert plate is stowed in the housing in the closing position. The exertion of the pinch force upon the locking clip can be applied by a user to the locking tab that goes through the locking hole.

In an embodiment, the insert plate may also have a releasing tab, where a user may open the insert plate only when squeezing the locking tabs together with sufficient force with one hand and pulling the releasing tab with the other hand simultaneously. In an embodiment, the insert plate may have a grip attached to an end, where the grip has angled side edges for stabilizing the insert plate when it is stowed in the housing in the closing position. The grip may also be positioned to be gripped to release the insert plate from the closing position and slide out of the housing.

The system may also include a dispenser shell that can be removably attached to the insert plate, where the dispenser shell has a face and multiple unit dose containers, each container having an opening through the dispenser face. Alternatively, the dispenser may also be an integral part of the insert plate. The system may also include a retainer sheet confrontingly affixed to the dispenser shell face to seal each container opening and to burst proximate to each opening as the unit dose is dispensed through the respective openings of the containers. The locking means may include an inner lining inside the housing, the inner lining having an edge arranged to block the at least one locking clip from sliding when the insert plate is at the closing position. The system may also have a stopping means disposed inside the housing for limiting outward sliding of said insert plate from the housing when the insert plate is released from the closing position. The stopping means may have an inner lining that has a cutout arranged to block the at least one locking clip from sliding outward when the insert plate is at a desired opening position.

In one embodiment, a senior friendly unitary dose dispensing system may include a housing that has at least two opposite side walls, an opening side between the two opposite side walls and at least one locking hole, which is on one of the two opposite side walls. The system also includes an insert plate that can be stowed in the housing in a closing position and slid out of the housing through the opening side in an opening position.

The system may also include one locking means for locking the insert plate to the housing, where the locking means has at least one locking clip having at least one locking tab. The at least one locking tab may be positioned to mate with a corresponding locking hole on the side wall of the housing, and is capable of extending through and outside of the locking hole when the insert plate is stowed in the housing in the closing position. The locking tab may also retract upon exertion of sufficient tip pinch force, through locking hole so that the insert plate is released from the closing position and slides out of the opening side of the housing to reach the opening position.

The system may also include a dispenser shell removably attached to the insert plate, where the dispenser shell has a face and multiple unit dose containers, each container has an opening through the dispenser face. The system may also include a retainer sheet confrontingly affixed to the dispenser shell face to seal each container opening and to burst proximate to each opening as the unit dose is dispensed through the respective openings of the containers.

The system may also include a sensor network arranged about the retainer sheet to have multiple frangible electrical container integrity signal paths, each path being positioned to substantially extend across a respective opening when the retainer sheet is affixed onto the dispenser shell face. The system may also have a circuit and battery for powering the circuit, both of which may be attached to the insert plate and electrically coupled to the sensor network and the circuit can record a time at each instance when one of the frangible signal paths is interrupted as the unit dose is dispensed. The circuit may also compute and record information related to one or more dispensings of the unit dose. The circuit may be in communication with a display and output the dispensing related information or a compliance code pertaining to one or more dispensings of the unit dose to the display or other peripherals or network.

In one embodiment, a method of recording compliance usage associated with using a unitary dosage child resistant and/or senior friendly dispensing system disclosed above may include the steps of detecting an interruption of the sensor network when an opening on the dispenser shell is bursted by a user; recording the compliance usage information about dispensing that includes at least a timestamp of when an instance of the sensor network interruption occurs; storing in a memory the compliance usage information; and outputting, the compliance usage information on the display upon receiving a user request.

In one embodiment, a non-transitory computer readable medium for storing program instructions for recording compliance usage information associated with using a unitary dosage child resistant and/or senior friendly dispensing system disclosed above, may include program instructions for causing a processing unit to (1) cause the circuit to detect an interruption of the sensor network when an opening on the dispenser shell is bursted by a user; (2) record compliance usage information about dispensing that includes at least a timestamp of when an instance of the sensor network interruption occurs; (3) store in a memory the compliance usage information; and (4) output the compliance usage information on the display upon receiving a user request.

### BRIEF DESCRIPTION OF THE DRAWINGS

FIGS. 1A and 1B depict examples of a housing of a dispensing system.

FIG. 2 illustrates an example of an insert plate of a dispensing system.

FIG. 3 illustrates an example of a dispenser shell.

FIG. 4 illustrates an example of a retainer sheet.

FIG. 5 illustrates attachment between a dispenser shell and retainer sheet according to one embodiment.

FIGS. 6 and 7 show one arrangement of a dispenser shell according to one embodiment.

FIGS. 8, 9 and 10 show one embodiment of a releasing tab.

FIGS. 11 and 12 show one embodiment of a releasing tab.

FIGS. 13A and 13B illustrate a grip of an insert plate according to some embodiments.

FIG. 14 illustrates an inside view of a locking and stopping means according to some embodiments.

FIGS. 15A and 15B illustrate an example of packaging and inner lining of the housing.

FIG. 16 illustrates an example of a monitoring system according to one embodiment.

FIG. 17 illustrates an example of a locking clip and mounting means.

FIGS. 18, 19, 20, 21 and 22 illustrate examples of a locking clip according to various embodiments.

FIGS. 23A and 23B illustrates an example of an insert plate of a dispensing system.

### DETAILED DESCRIPTION OF THE INVENTION

As used in this document, the singular forms “a,” “an,” and “the” include plural references unless the context clearly dictates otherwise. Unless defined otherwise, all technical and scientific terms used herein have the same meanings as commonly understood by one of ordinary skill in the art. As used in this document, the term “comprising” means “including, but not limited to.”

The term “child-resistant” as used in this disclosure means that the system, device, container, packaging or storage vessel is designed or constructed to be significantly more difficult for a child or children to open and remove from the vessel the solid, liquid and/or soft gel pharmaceutical material, while not difficult for normal adults to use properly. By “senior friendly” it is intended to describe a package that is designed to allow senior and physically abled adults to open the package readily while facilitating easy compliance with the designated dosing regimen of the prescribed medication.

The term “child” in the context of “child resistant” could be categorized by the way of age, hand size, and force between his/her thumb tip and index fingertip. Examples according to the present invention a child may be under 12 years of age, under 8 years of age, or under 5 years of age and/or may be associated with a unique value for their hand size or grip strength, for example, the value of the force that can be applied by the thumb tip and the index fingertip, the mean tip pinch force, is below 10 pound-force, for example below 7 pound-force.

As used herein, the term “dispensing system,” “container” or “unit” refers to any type of storage vessel for holding solid and/or liquid pharmaceutical material, including but not limited to pills, tablets, caplets, capsules, gel caps, perils, powder, packets, or other pharmaceutical solid and/or liquid dosage forms.

The terms “inward” and “outward” refer to a direction toward and away from, respectively, the geometric center of the device and designated parts thereof. The terms “inward” and “outward” may also refer to a direction to inside or outside of the dispensing system housing when they are used in the context of sliding movement.

In one aspect, a child resistant senior friendly dispensing system has a housing and an insert plate that can slide in or outside of the housing. The system has a locking means for locking the insert plate to the housing when the insert plate is completely stowed inside the housing. The locking means has a locking clip, which has at least one locking tab and is mounted on the insert plate at one end. When the insert plate is stowed inside the housing in a closing position, the at least one locking tab on the locking clip is positioned to mate with a corresponding locking hole on the side of the housing and automatically extends outside of the housing through the corresponding locking hole. Alternatively, and/or additionally, the housing may not have a locking hole, and the locking clip may be hidden inside the housing completely. The locking clip can still be pressed inward by a user, exerting a pinching force from outside the housing at where the locking clip is positioned, to release the locking means. To open or slide out the insert plate from the housing, a user will need to release-and-pull, i.e. to press the at least one locking tab on the side of the housing to release the locking tab and pull the insert plate simultaneously.

In one embodiment, the dispensing system can be made child resistant, in that the housing can have two locking holes, each on one of two opposite side walls of the housing, and the locking clip has two locking tabs, each arranged to engage with one of the locking holes on the side walls of the housing. The release-and-pull will require a user to squeeze, press or tip pinch both locking tabs on both sides of the housing simultaneously to be able to release the insert plate from the stowed position. With the release-and-pull mechanism, the locking means will prevent the insert plate from being easily opened by a child while still allowing an adult to open without difficulties. In another embodiment, the locking clip requires exertion of sufficient force on the locking tabs in order to release the insert plate from its stowed closing position, preventing a child of small age from opening it. In another embodiment, the width of the housing, or the lateral distance between the locking holes is large enough that it requires an adult's hand to press both locking tabs with one hand, thus preventing a child of small hands from opening it.

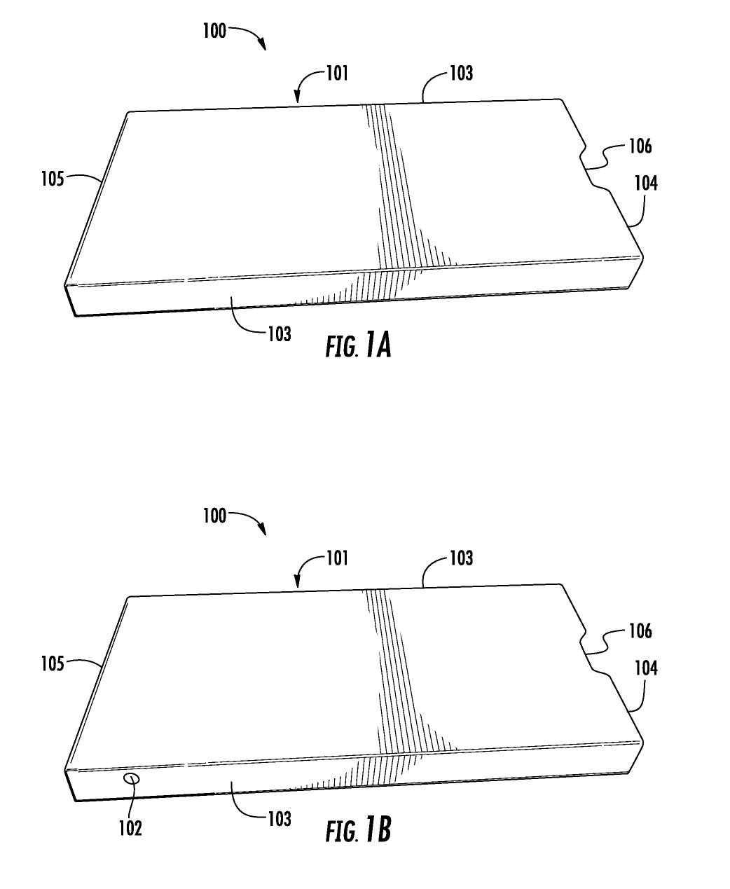

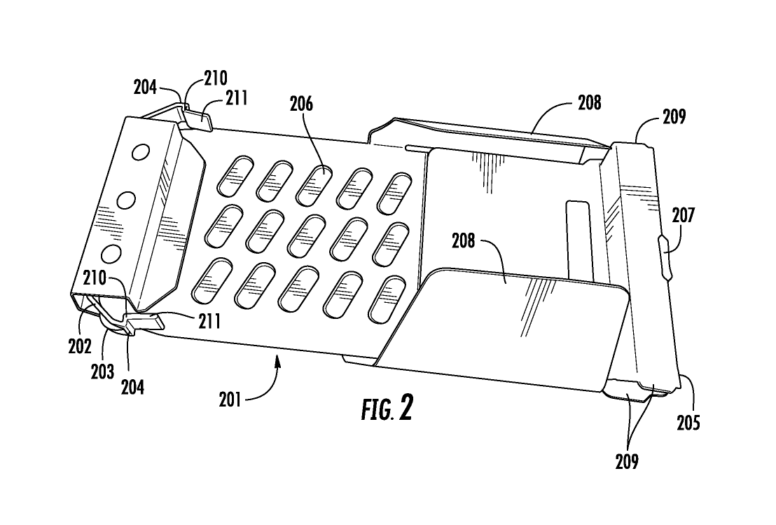

The child resistant dispensing system is further explained by the way of figures described herein. According to an embodiment shown in FIG. 1A, the dispensing system 100 has a housing 101, which has two opposite side walls 103 and at least one opening side 104 between the two side walls 103. The housing may also have a side 105 that is opposite to the opening side 104 and that may include an end wall. An insert plate (201, shown in FIG. 2) can slide in and outside of the housing 101 through its opening side 104. Optionally, as shown in FIG. 1B, each side wall may have a locking hole 102 distal from the opening side.

With reference to FIG. 2, the insert plate 201 may have a locking means, which has a locking clip 202 mounted to one end of the insert plate 201. In one embodiment, the locking clip 202 has two ends facing each other, and forming an open jaw. Each end has a ridged edge 204. The ridged edges 204 may be formed by two portions of the locking clip intersecting at an acute angle and optionally forming a groove 210 or a flat surface. Each end of the locking clip may further extend to include a tail piece 211. In one embodiment, the tail piece 211 may also function as a physical stabilizer of the package by adding a weight. The tail piece 211 may also form as part of a stopping means and is positioned to engage with a stopper or a barrier so that the insert plate is prevented from coming out of the housing completely. Optionally, each end may also have a locking tab 203 that has a raised surface area.

The locking clip 202 is made of high density flexible ABS plastic material such that each end of the locking clip can be squeezed and/or pushed inward with an exertion of certain force upon the locking tab and when the force is released, the ends of the locking clip will move back outward to its previous position. In a preferred embodiment, the locking clip 202 is formed of material capable of absorbing the force and exhibiting elastic and shape memory characteristics, so that it would return to its original shape upon the removal of the force. In a more preferred embodiment, the locking clip 202 withstands physical and environmental stress for at least 5 years without substantially exhibiting deformities. In one embodiment, the locking clip is attached across the width of the insert plate on one end in a flattened position such that each end of the locking clip is pointing to the opposite end of the insert plate 205 and the two ridged edges 204 become vertical with respect to the insert plate.

At its default closing position, the insert plate is stowed inside the housing. In one embodiment, the locking tabs 203 may be positioned to mate with the locking holes 102 (FIG. 1) on the housing side walls, thus the locking tabs 203 are automatically engaged with the locking holes by extending outside of the housing through the locking holes. When this occurs, the ridged edges 204 will engage with a part of the locking means inside the housing, so that the locking clip is prevented from sliding outward towards the opening side of the housing. When the locking tabs are tip pinched inward with sufficient force, the ridged edges of the locking clip will be dislodged from the locking means inside the housing and the insert plate can slide out of the housing with slight pulling force. It requires the user to pinch the two locking tabs with one hand and pull the insert plate with the other hand simultaneously in order to slide open the insert plate from the housing to reach a desirable opening position, so the insert plate can be accessible to the user to retrieve therapeutic pills from unit dose containers, which will be explained below. Alternatively and/or additionally, when the housing does not have locking holes, the locking clip may be hidden inside the housing completely, and the locking clip may not need to have locking tabs. The locking clip may still be configured the same way so that a user may pinch the lock clip from the side of the housing at where the two locking tabs are located. The housing can have markings outside the housing at or about the location that corresponds to the locking tabs of the locking clip when the insert plate is fully stowed in the housing, so that the user can easily open the packaging while it is not apparent for a child to operate.

In one embodiment, as shown in FIG. 3, a dispenser shell 301 may be removably attached to the insert plate 302. The dispenser shell may have a face, which defines multiple unit dose containers or compartments 305 and each container defines an opening through the dispenser face. The containers 305 are configured to receive single and multiple unit doses of medicaments of various forms. In one non-limiting configuration, each container on the dispenser shell may receive one or more pills or tablet medicaments. In another configuration, each container may receive two capsules and one tablet of medication to be consumed in one single dose.

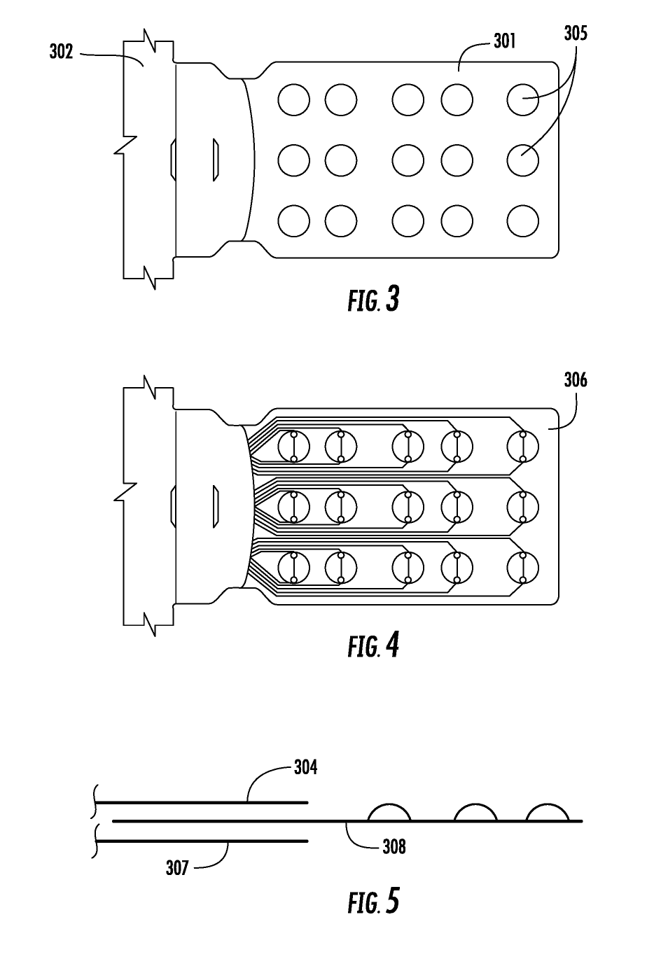

With reference to FIG. 4, a retainer sheet 306 may be configured to be confrontingly affixed to the dispenser shell face to seal each container opening and to burst at or proximate to each opening as the unit dose is dispensed through the respective openings of the containers. A single or multiple layers of retainer sheet may be affixed to the dispenser shell. The affixation may incorporate various known or later developed methods, such as using adhesive, heat molding or sealing or ultrasonic and infrared plastic welding technologies. For improved dispensing of the unit doses, the retainer sheet 306 may be adapted to incorporate a pre-scored or slotted aperture control groove, or other known or later developed techniques, to lessen the force needed to dispense the unit dose through the retainer sheet. In one embodiment, the dispenser shell coupled with the retainer sheet may be in the form of a blister package.

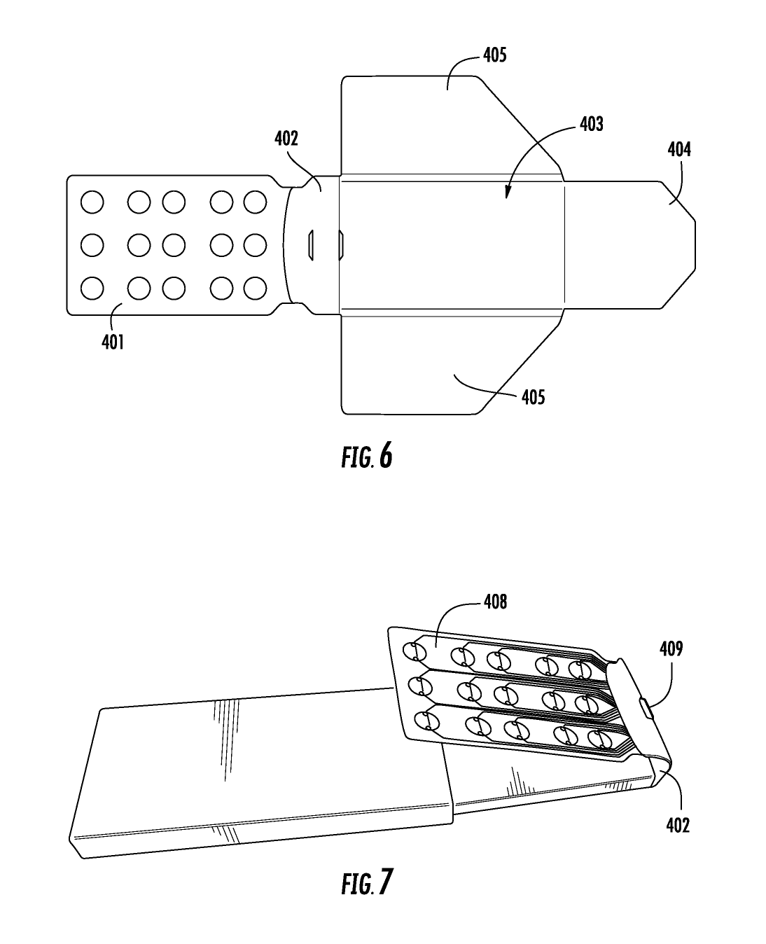

There may be various ways of attaching and placing the dispenser shell to the insert plate. In one embodiment, with reference to FIG. 5, the insert plate may be made of multiple layers 307 of cardboard and/or plastic, and the dispenser shell 308 may be bonded in between the multiple layers of the insert plate 307 by gluing or using other adhesive materials. In terms of placement of the dispenser shell, in an non-limiting configuration, with reference to FIG. 6, the dispensing system may be a folded pack, in which the dispenser shell 401 may be attached to one end 402 of the insert plate 403. This end 402 is adapted to act as a hinge so that the dispenser shell (and retainer sheet affixed thereto) can be folded towards an opposite end 404 and arranged to be laid over the insert plate 403. The opposite end 404 can be configured to receive the locking clip to be mounted thereto. The insert plate 403 may also have two flaps 405 that are adapted to be folded inward towards each other to cover the dispenser shell such that the insert plate essentially wraps around the dispenser shell inside and protects the dispenser shell from scratching with the housing when the insert plate is sliding in and out of the housing. In one embodiment, the insert plate may not contain one or both flaps. Alternatively, the insert plate 403 may have only one or no flaps.

In one embodiment, with reference to FIG. 7, when the dispenser shell 408 is folded onto the insert plate, whereas the end of the insert plate 402 is configured to be a closing side wall such that, when the insert plate is completely stowed inside the housing, the closing side wall is flush with the opening side of the housing thus to close the housing.

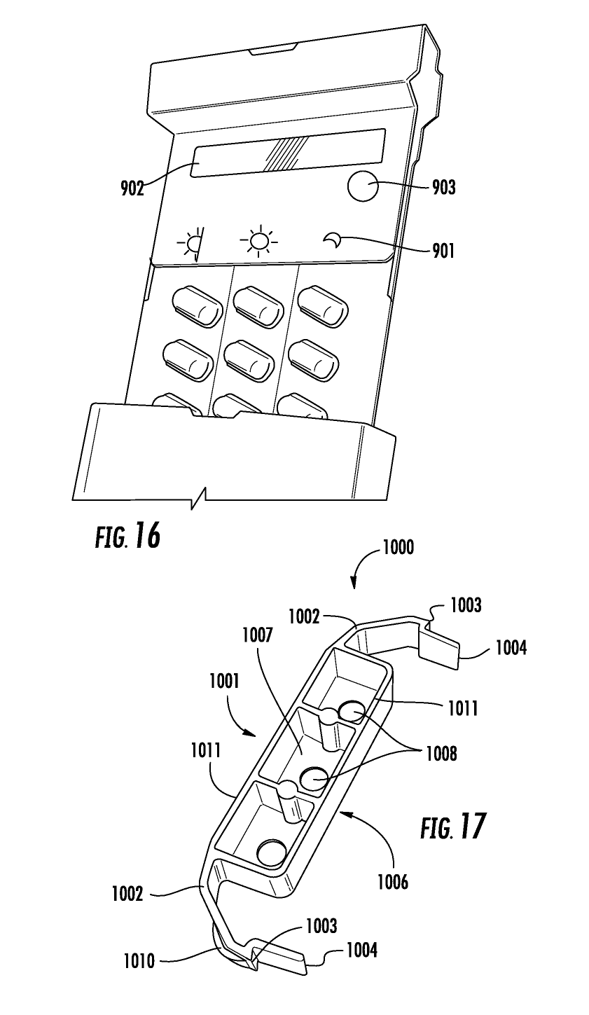

In one embodiment, with reference to FIG. 2, the dispensing system may be straight-slide pack, in which the dispenser shell 206 is disposed directly on the insert plate 201. For example, the dispenser shell can be permanently attached to the insert plate as an integral part of the insert plate. In one embodiment, the dispenser shell may be configured to be an insert plate, and extend the dimension beyond the dispenser shell to allow the locking clip 202 to be mounted thereon on one end. On the opposite end, the insert plate can be folded to form a closing side wall 205, and extend further to display printed user instructions or install a human-machine interface circuit with a cutout for a display such as a LCD screen or other user actuatable buttons or widgets (also see FIG. 16). In one embodiment, the closing side wall 205 is aligned or flush with the opening side of the housing when the insert plate is stowed inside the housing.

Similarly, the insert plate can have two flaps 208 extending from each lateral side of the insert plate, the flaps can fold inward towards each other to form a protective shell to the dispenser shell. In such configuration, the dispenser shell can be directly stowed into the housing without folding. In one embodiment, the insert plate can have only one flap on one side or be without flaps. In one embodiment, the protective shell may be positioned to fit into the housing and functions to prevent the insert plate and/or multiple unit dose containers from being scratched by the housing when the insert plate slides in and out of the housing. In one embodiment, the protective shell may be sized to be in contact with the inside of the housing when the insert plate is stowed in the housing in the closing position such that the insert plate and/or the multiple unit dose containers are prevented from movement in the housing.

With further reference to FIG. 2, the insert plate can have one or two wingtips 209 on each side. In one embodiment, the wingtip may be part of the insert plate and extrude slightly from the side of the insert plate to form a wing adjacent or near the closing wall 205 and configured to be inside the housing when the insert plate is stowed in the closing position. The wingtips, when inside the housing, will constantly contact with the inside surface of the housing or inner lining of the housing, thus it allows no lateral movement of the insert plate, which helps stabilize the insert plate when it is stowed in the closing position. This will help eliminate undesirable noise or wiggling of the insert plate during the handling of the package.

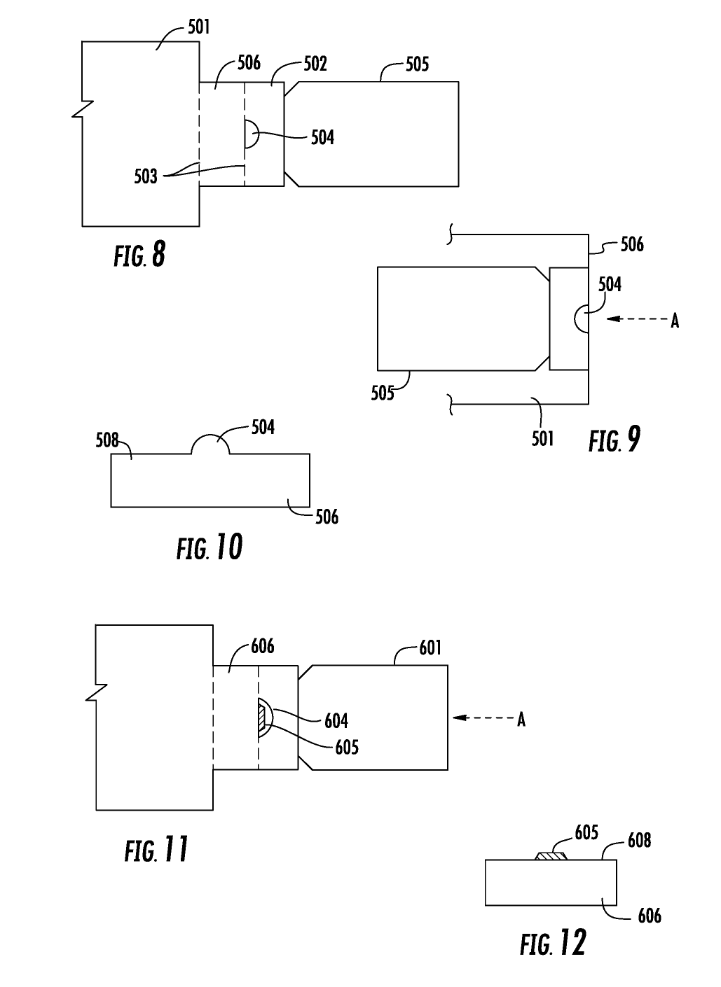

With further reference to FIG. 2 and FIG. 7, the closing side wall 205, 402 can have a releasing tab 207, 409, respectively, to aid the opening or pulling of the insert plate by providing a grip for the user. In one embodiment, the releasing tab can be made from the insert plate without requiring additional components or materials. For example, in FIG. 8 (the top view when the dispenser shell is unfolded), the insert plate 501 may have an extended end 502 to be used to attach the dispenser shell 505. The extended end 502 may be configured to fold over onto the insert plate 501, together with the dispenser shell, at two folding lines or hinges 503 such that the area between the folding lines or hinges 506 becomes the closing side wall, as shown in FIG. 9 (the top view when the dispenser shell is folded). On a portion of the extended end 502 of the insert plate and near the folding line or hinge that is further away from the insert plate, there can be a cutout 504, which forms as a releasing tab, as shown in FIG. 9. In one embodiment, the cutout 504 can be of a shape of a half-circle to accommodate a user's thumb.

In one embodiment, the top side of the housing may have a cutout (106 in FIG. 1) at the edge of the opening side 104 such that the cutout 106 is aligned with the cutout 504 of the insert plate when the insert plate is completely stowed inside the housing, allowing user's finger to grip the releasing tab 504 and pull the insert plate while simultaneously pinching the first and second locking tabs on both sides of the housing. Returning to FIGS. 9-11, in another embodiment, instead of cutting out 504 at the extended end 502, the curved outline of the area 504 can be pre-cut, leaving the material of 504 pivoting about the straight line 503. When the dispenser shell is folded onto the insert plate, this area 504 becomes part of the closing side wall 506 and extends beyond the top side of the housing 508, as shown in FIG. 10 (side view from the perspective angle of “A” in FIG. 9 when the dispenser shell is folded onto the insert plate), acting as a releasing tab.

Alternatively and/or additionally, the release tab can be fabricated directly from the other materials, such as the materials used for dispenser shell. With reference to FIG. 11, when the dispenser shell 601 is bonded in between layers of insert plate, the insert plate may have a cutout 604 near a folding line or hinge, and a small piece of the dispenser shell may extrude slightly 605 so that it is encompassed by the cutout area 604. When the dispenser shell is folded onto the insert plate, this extruded area of the dispenser shell 605 becomes part of the closing side wall 606 and extends beyond the top surface of the housing 608, as shown in FIG. 12 (side view from the perspective angle of “A” when the insert plate is folded), acting as a pulling tab.

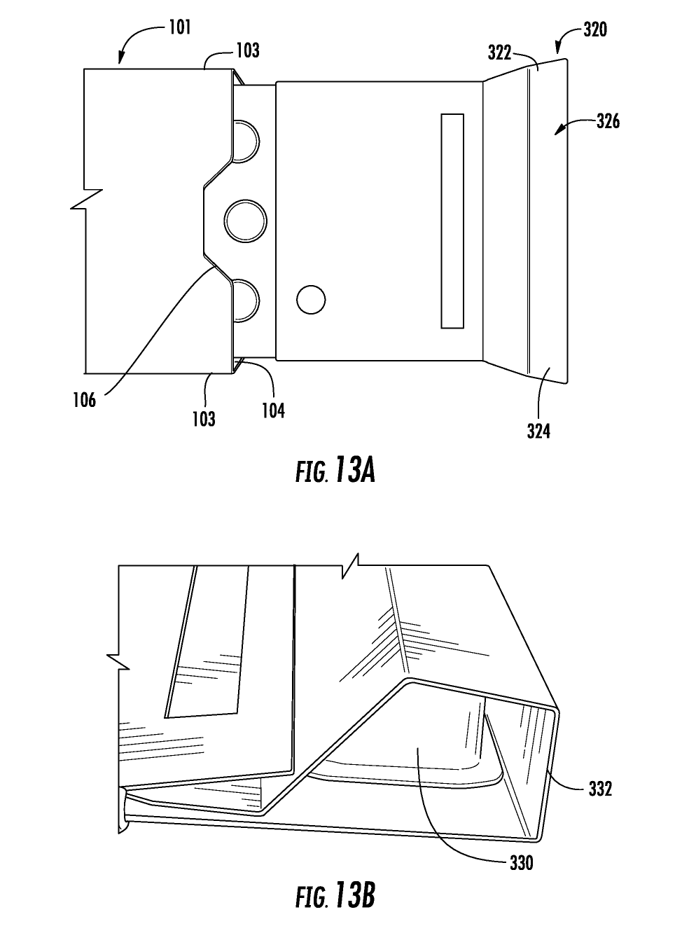

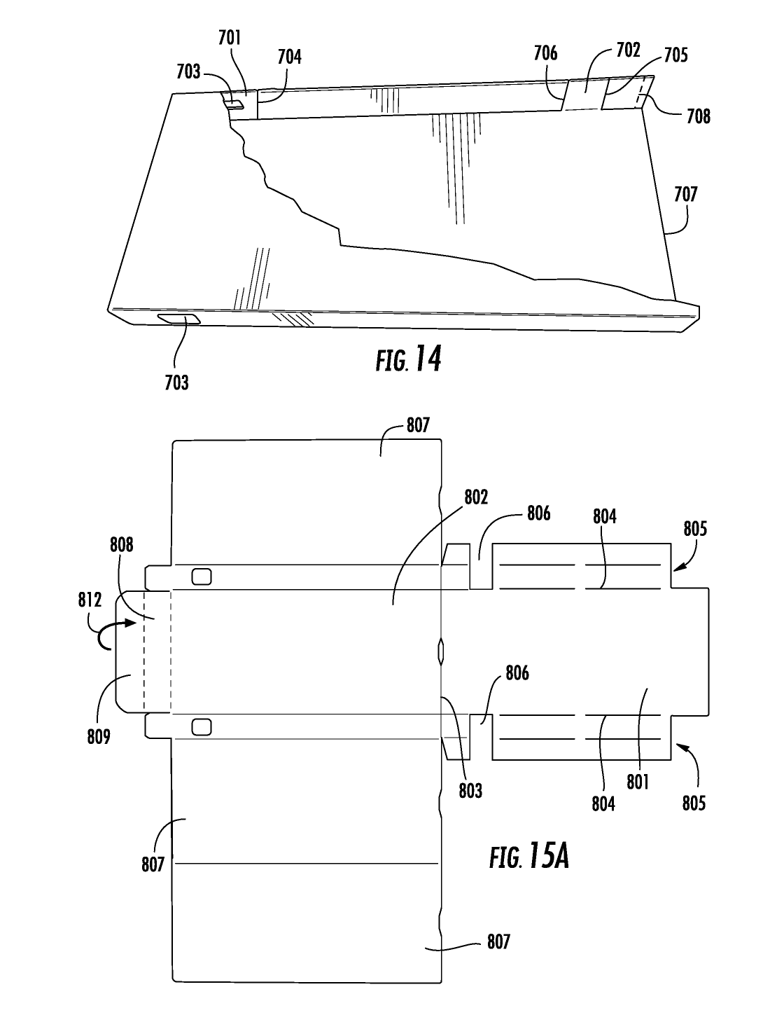

In some embodiments, the insert plate can have no releasing tab (207 in FIG. 2). For example, as shown in FIG. 13A, the insert plate may have a grip 320. The grip 320 may be attached or formed on an end of the insert plate that is opposite to the locking means (not shown). The grip 320 may have a side 326 that is configured to be flush with the opening side 104 of the housing 101 when the insert plate is stowed in the closing position. The grip 320 may also have angled opposing edges or protruding extensions 322, 324, which are angled inward from the side 326 towards the opposing end of the insert plate where the locking means is disposed. In such a way, the angled opposing edges or protruding extensions 322, 324 will be in contact with the side walls 103 of the housing 101 when the insert plate is stowed in the closing position, so that the insert plate can be stabilized and prevented from lateral movement in the housing. The illustrated embodiment of the grip 320 can work with a cutout 106 of the housing 101 (shown in FIG. 1 and FIG. 13A), so that at least a portion of the grip will be exposed through the cutout 106. This allows the insert plate (grip) to be grabable near the cutout 106 so that the insert plate can be released from the closing position and slide out of the opening side 104. Alternatively, and/or additionally, the cutout can be either at the center, on the left or right side of the housing unit.

In some embodiments, the grip may be constructed in a sturdy shape for easy gripping. For example, as shown in FIG. 13B, the grip may be formed by wrapping around the insert plate at the end. Alternatively, the grip may be built in a wrapped around structure 332 that is attached to the insert plate. To make the grip sturdy or to prevent the grip from collapsing from excessive force asserted by the user, the grip may include an insert 330. In one embodiment, the insert 330 of the grip may be by any sturdy materials, such as molded polyurethane, plastic or card board.

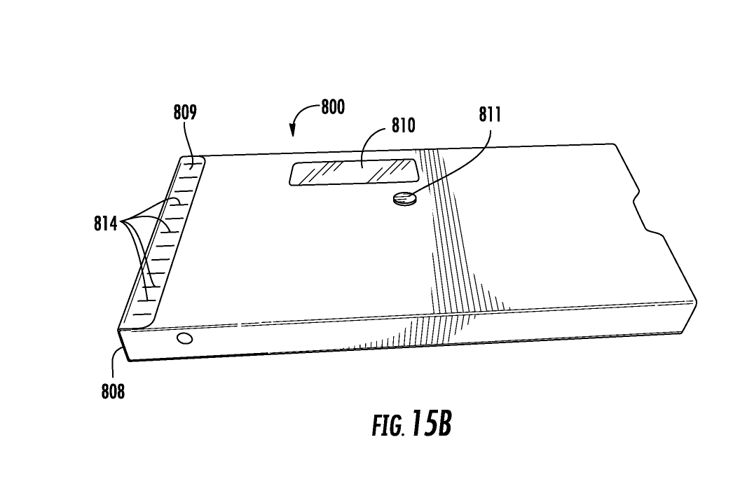

With reference to FIGS. 2 and 14, the locking means is further explained by way of example. In one embodiment, the locking means may include an inner lining against inside surface of the housing, the inner lining may cover inside of both side walls of the housing. The locking means may include a recess area 701 surrounding the locking holes 703. The recess areas 701 can be formed by a cutout from the inner lining on each side wall, while the cutout forms an edge 704 proximate to the locking hole on each side wall. The edges 704 is configured to engage with the locking clip 202 to block the locking clip from sliding outward. When the insert plate is fully stowed in the housing in its closing position, the raised locking tabs 203 extend outside of the housing through the locking holes 703, allowing the ridged edges 204 to expand naturally outward and fall into the recessed area 701 and touch the inside surface of the housing. When a user tries to pull the insert plate outward the ridged edges 204 will attempt to slide along the inside surface of the housing and touch the inner lining edges 704, which will block the ridged edges 204 from further sliding, thus the insert plate stays locked in the closing position. To release the insert plate from the closing position, a user may tip pinch the locking tabs inward towards each other, causing the ridged edges 204 of the locking clip to be dislodged from the inner lining edges 704. When this occurs, and when user pulls the releasing tab simultaneously, the insert plate may freely slide outward through the opening side of the housing.

On each side wall, the placement of edge 704 depends on the distance between the ridged edge 204 and the center of the locking hole 703. Since the raised locking tab 203 is to mate with the locking hole 703 when the insert plate is in the closing position, the distance from edge 704 to the center of the locking hole 703 is ideally slightly larger than the distance between the ridged edge 204 and the center of the locking tab 203. This will help the ridged edge 204 to fall into the recess area 701 by leaving a small space between the ridged edge 204 and the inner edge 704. In one embodiment, this small space is less than 5 mm, but preferably less than 3, 2, 1 or 0.5 mm.

With further reference to FIGS. 2 and 14, the dispensing system may include a stopping means that includes a recess area 702. The recess area 702 can be formed by a cutout from the inner lining adjacent to the opening side of the housing. In one embodiment, on each side wall, the cutout from the inner lining may have two vertical edges, i.e. an outer edge 705 (proximal to the opening side of the housing) and an inner edge 706 (distal from the opening side of the housing). When the insert plate is released from the closing position and slides outside of the housing to reach a desired opening position, the ridged edge 204 of the locking clip 202 (FIG. 2) passes the inner edge 706 and falls into the recess area 702. When the insert plate continues to slide out beyond the desired opening position, the ridged edge 204 will start touching the outer edge 705 of the inner lining, which will block the ridged edge 204 from further sliding and coming through the opening side of the housing, thus stopping the insert plate at the desired opening position. Alternatively, the recess area 701 or 702 can be in any other functional shape, for example a circle, a rectangular, a square or a triangular, which can be positioned to accomplish the locking or blocking of the insert plate.

The placement of the recess area 702 can be configured to accommodate the desired opening position. In one embodiment, the center of the recess area is proximal to the opening side 707, at a distance about 10% of the longitudinal length of the housing. The size of the recess area 702 is determined by the placement of inner and outer edges 706, 705 of the inner lining. In one embodiment, the size of the recess area is configured that, when the user is sliding the insert plate outward, the ridged edges of the locking clip (204 in FIG. 2) fall into the recess area shortly before the insert plate reaches the desired opening position, thus giving a user a feel that the maximal opening is soon to reach. The size of the recess area 702 may also be configured to be large enough to contain the locking tabs when the insert plate is at the desired opening position. The recess area can be configured to have any other functional shape to facilitate the sliding and blocking of the insert plate. In some embodiments, the recess area 702 may be configured to any functional shape or design, i.e. circular, triangular, oval or the like, to prevent further outward sliding of the insert plate. In order to retract the insert plate inward, the user is required to give a slight push to force the locking tabs out of the recess area 702. This will help the insert plate stay in its desired opening position. In one embodiment, the size of the recess area 702 is about 13 mm longitudinally With the center of the recess area 702 being proximal to the opening side 707 at a distance less than 20%, 15% or preferably of about 10% of the longitudinal length of the housing, the longitudinally distance between the outer edge 705 and the opening side 707 of the housing ranges between 10-15 mm, and preferably about 12 mm.

Alternatively, and/or additionally, a barrier or stopper 708 can be mounted inside the housing side wall proximate to the opening end 707, e.g. at or near the area of the opening end of the housing. For example, the barrier may be at 1-3 mm from the opening end of the housing. The barrier 708 may extrude from the inside of the housing side wall to function as a stopping means by blocking the tail piece 211 (FIG. 2). This stopping means can be a substitute for the recess-based stopping means disclosed above, or function as a secondary stopping means that co-exist with the recess-based stopping means. Alternatively, and/or additionally, the housing may also have a barrier mounted inside the housing and positioned adjacent or near the opening end 707, and the barrier can be configured to block the locking clip from sliding out of the housing. In one embodiment, the barrier can be mounted to inside surface of the housing, for example, underneath the top side of the housing. In another embodiment, the barrier can be part of the inner lining of the housing. In one example, the barrier can be positioned at or near the middle of the housing laterally to be aligned with the mid-part of the locking clip. As appreciated by a person ordinarily skilled in the art, other distances or variations may still be within the scope of the teachings disclosed herein.

With reference to FIGS. 15A-B, a non-limiting example of inner lining is shown although other variations can be appreciated by a person with ordinary skill in the art. In one embodiment, the inner lining 801 and the housing 802 may be made of the same sheet material such as a plastic and/or a cardboard, with a folding line 803 in between. The folding line is also along the opening side of the housing, allowing the inner lining 801 to be folded and disposed inside of the housing against the inside surface of the housing. The inner lining 801 may include a longitudinal folding line 804 on each side so that each side of the inner lining may be folded longitudinally to be disposed inside the housing against each side wall. Each side of the inner lining 801 may include a cutout 805 that can form a recess area in the locking means (see 701 in FIG. 14) when the inner lining is folded against the inside surface of the housing. Further, each side of the inner lining 801 may include a cutout 806 that, when the side of the inner lining is folded against the inside surface of each of the side walls, forms the stopping means (see 702 in FIG. 14). The inner lining, when folded against inside surface of the housing, can be bonded to the inside surface of the housing (including side walls) using a glue or other adhesives.

With further reference to FIGS. 15A-B, the housing sheet material 802 may extend laterally to include sheet material 807 that can be wrapped around and used as bottom side of the housing. The housing sheet 802 may also extend longitudinally to include a portion 808 that can be folded to form a closing end wall of the housing and a portion 809 that can be folded towards the center of the housing sheet (as shown in direction 812) and bound to the top or bottom side of the housing 800 to seal the closing end wall 808. In another embodiment, the housing and inner lining can be made of other materials, such as materials mimicking cardboard and/or plastic, and/or other known or later developed materials. In another embodiment, the housing and/or the inner lining can be molded.

In one alternative embodiment, the extended portion 809 of the packing can be bound to the top or bottom side of the housing by an adhesive material, such as a glue. In other embodiments, the extended portion can be hot glued, stitched, or glue pressed (as shown in multiple strips 814) to reinforce the bounding strength, to prevent a child from easy tearing and force opening the packaging. In one embodiment, the housing sheet 802 or the sheet material 807 may be made with strong materials, such as strong cardboard, laminated cardboard, vinyl or polycarbonate sheet to ensure resistance to child tampering.

Returning to FIG. 1, the locking holes 102 on each of the side walls is located at a longitudinal distance from the opening side 104 of the housing 101. This longitudinal distance can vary. In one embodiment, this distance is at a range between about 75% and 100% of the longitudinal length of the side wall. In another embodiment, the distance can be between 90% and 99% of the longitudinal length of each corresponding side wall. The lateral distance between the locking holes 102 on each of the side walls may also vary depending on the configuration of the housing/packaging. In one embodiment, the lateral distance between the locking holes can be in the range between 64 and 88 millimeters. In another embodiment, the lateral distance can be in the range between 72 and 80 millimeters. In another embodiment, the housing and the dispenser shell can be made small or large to accommodate various dosages, for example, a 7-day package or a package for more than a week of supply, such as a 15-day or 30-day package. For example, the longitudinal length of the housing can be in the range between 150 and 160 millimeters for small packages and between 180 and 200 millimeters for larger packages. The lateral distance between the locking holes can be in the range between 30 and 90 millimeters. Similarly, the height of the housing/packaging can vary. For example, in a package for one tablet per day (or per blister opening), the height of the housing can be in the range between 8 and 12 millimeters.

Returning to FIG. 2, the locking tabs 203 on each end of the locking clip 202 can be an integral part of the locking clip, and can have a surface extruding from each end of the locking clip such that the extruded surface may be positioned to mate with the corresponding locking holes and extend outside of the housing through the corresponding locking holes while the rest of the locking clip may not. The extruded surface may be of different areas and shapes in order to maximize the contact surface between finger(s) of an adult and the locking tab(s) during the exertion of the force. For example, the raised surface of the locking tab can be circular, parallelipidic, triangles, ovals, rectangles, arrows, squares, trapezium, parallelograms, pentagons or hexagons. Similarly, the locking hole can also have a shape of circular, parallelipidic, triangles, ovals, rectangles, arrows, squares, trapezium, parallelograms, pentagons or hexagons so that the locking hole and the locking tab can be mated together when the insert plate is stowed in the housing in the closing position.

In one embodiment, the surface of the locking tabs 203 may be of the shape of a portion of a wheel (because of the curvature of the locking clip, as shown in FIG. 2), whose exposed surface area can be in the range of 3-4 mm by 7-8 mm or between 20 and 30 mm² and a thickness of about 1.2-1.6 mm. In order for the locking means to operate smoothly, the extruded surface area of each locking tab can be slightly smaller than the area of each of the locking holes such that the locking tabs can extend through the locking holes without much friction, allowing the locking tabs to expand naturally when the locking tabs are each mated with the corresponding locking holes. In one embodiment, the extruded surface area of each of the locking tabs can be between 75% and 99.9% of the area of the corresponding locking hole on the side wall of the housing.

According to another aspect, a senior friendly dispensing system may not require the release-and-pull action as required by the child resistant dispensing system, or that a user must exert tip pinch force upon two locking tabs simultaneously in order to release the locking means. In one embodiment, the senior friendly dispensing system can have a housing with two side walls and an insert plate that can slide in or outside of the housing. The system may have a locking means for locking the insert plate to the housing when the insert plate is completely stowed inside the housing. In one embodiment, the locking holes may be covered and not apparent externally or from outside surface, yet capable of mating with a corresponding locking tabs to achieve a proper locking. The locking means may have a locking clip, which has at least one locking tab and is mounted on the insert plate on one end. When the insert plate is stowed inside the housing in a closing position, the at least one locking tab on the locking clip is positioned to mate with a corresponding locking hole on at least one of the side walls of the housing and automatically extends outside of the housing through the corresponding locking hole. To open or slide out the insert plate from the housing, a user will need to press the at least one locking tab on either one of the side walls of the housing to release the locking means and pull the insert plate simultaneously.

In one embodiment, with reference to FIG. 16, the senior friendly dispensing system may further include easy compliance icons 901 printed on the dispenser shell, next to each row or column of openings that contain the pills or tablets. In one embodiment, the icons may include “morning” “noon” or “PM” or alike. The senior friendly system may also include a sensor network, a circuit and a power source, e.g. a battery, for monitoring and reporting compliance, which is disclosed in the U.S. Pat. No. 6,973,371, the contents of which is incorporated herein by reference in its entirety. In one embodiment, the senior friendly system may include a display 902, such as a LCD, for displaying the reporting result, and one or two user actuatable buttons 903 for activating or outputting compliance monitoring results.

In one embodiment, the display and/or one or more actuatable buttons can be attached to the dispenser shell or part of the insert plate. When the user is required to report compliance results, the user may slide the insert plate from the housing and read the result on the display and/or push one of the actutable buttons for reporting. Alternatively, the display 810 and/or one or more actuatable buttons 811 may be attached to an outside surface of the housing 800 (shown in FIG. 15B) so that the user does not need to slide out the insert plate in order to report compliance results. In one embodiment, the display and/or actuatable button can be electrically connected to the sensor network inside the housing, e.g. via a wire or conductive ribbon.

The sensor network may monitor each of the dispenses when a user dispenses pills/tablets from any of the openings on the dispenser shell. In one embodiment, the sensor network can be arranged about the retainer sheet to have a plurality of frangible electrical container integrity signal paths, each path being positioned to substantially extend across a respective opening when the retainer sheet is affixed onto the dispenser shell face. Each path is connected to a power bus and a ground bus such that when a user bursts an opening on the dispenser shell the corresponding path that runs through or proximate to that opening is interrupted and forms an open circuit.

In one embodiment, the system may have a circuit attached to the insert plate and electrically coupled to the sensor network to detect the open circuit at each instance when a one of the frangible signal paths is interrupted as the unit dose is dispensed. The circuit may record a time at each instance when the unit dose is dispensed, and compute and store a compliance reporting result in a memory for later retrieval. The system may include a display, such as a LCD, a glass or flexible display that is in communication with the circuit and, upon user's push of “compliance” button, display the compliance result that can be retrieved by the circuit from the memory. The compliance result may include any useful information related to the dispensing of medications, such as the time and date of the opening of the container retainer sheet and/or the positioning of the opened container retainer sheet, and/or an average time interval among one or more dispensings of the unit dose, whether a user is complying with the schedule required of the prescription. In one embodiment, these information can advantageously be embedded in one or more compliance codes.

The system may have human-machine interface, for example, via a display (text, graphics, video) or audio (e.g. speaker), to output the dispensing related information to a user. For example, a user may push on the compliance button 903 to access the compliance code and the user may provide or submit the compliance code to an appropriate authorized entity (doctors, pharmacist, etc.). Alternatively and/or additionally, the system may have a communication interface, wired or wirelessly, to be able to advantageously transmit dispensing related information or compliance code to a local or remote electronic device, such as a mobile phone, a laptop, a tablet computer, or a remote server. The system further enables an authorized entity to receive or generate compliance report and further implement appropriate therapeutic intervention to enhance patient compliance by sending compliance reminders through appropriate communication channels or making direct contact with the respective patients and ultimately verify patient medication consumption. The system may also be interfaced with health organizations databases such as hospital pharmacy or nursing units to ease monitoring patient medication records.

Additionally, and/or alternatively, the system may include a micro-processor or processing unit to accomplish more sophisticated computation for compliance reporting. For example, the system may display a history of past dispenses with date and time logs. In another embodiment, the system may automatically send alerts (e.g. blinking of the display or audible sounds). In another embodiment, the system may include a wireless or wired communication interface that can be in communication with a host computer (server) or a portable electronic device (e.g. a mobile phone) via a communication network. The host computer (server) or portable electronic device may use the communication network to be able to download the compliance reporting data from the memory onboard the dispensing system. For example, the system may allow a mobile phone to communicate with the dispensing system via Bluetooth protocol, to retrieve the compliance reporting data and display the result on the mobile phone display. In another embodiment, the compliance reporting data can be retrieved via a wired or wireless communication interface by a remote device. In one embodiment, the receiving device, after retrieving the compliance reporting data, may, via a processing device, use the compliance code to generate a report that includes information about patient medication intake. The report may also contain information that highlights patient compliance to evaluate cross compliance based on patient's objective or subjective response to the medication therapy. Response to the medication therapy may include measuring medication related adverse events or monitoring surrogate therapeutic parameters, such as lab indices, indicating overall improvement in patient's health.

In fabricating the sensor network, in one embodiment, the plurality of frangible electrical container integrity signal paths can be made of conductive ink disposed on a substrate. The substrate may be disposed between the retainer sheet and the conductive ink. In another embodiment, the substrate may be the retainer sheet itself, on which the conductive ink can be directly deposited. The substrate and/or the retainer sheet may be made of metal (e.g. aluminum or copper), paper, or cardboard or thin plastic film with or without a precut holes proximate to each of the opening on the dispenser shell.

In connecting the sensor network to the circuit, in one embodiment, various adhesives such as ACF (Anisotropic conductive film)/adhesive bonding, conductive adhesive glue or conductive adhesive gel, can be used. In another embodiment, the sensor network and the circuit can made of a single layer that is made from etched metal, such as aluminum or copper, eliminating the process of bonding between the sensor network and the circuit. In one embodiment, the single layer can also be made from a functional printing process. As can be appreciated by a person ordinarily skilled in the art, the sensor network, compliance reporting and monitoring system can also be included in a child resistant dispensing system.

With reference to FIG. 17, the locking means is further described in detail. The locking clip can be made of a single elastic piece that can exhibit elastic properties, i.e. is capable of being subjected to sufficient compression during the releasing of the locking means so that a child cannot open the package. In a preferred embodiment, the locking clip is formed of material capable of absorbing the force and exhibiting elastic and shape memory characteristics, so that it would return to its original shape upon the removal of the force. In a more preferred embodiment, the locking clip withstands physical and environmental stress for at least 5 years without substantially exhibiting deformities. In another embodiment, the locking clip is made to be capable of coming back naturally to its initial shape and mating with the corresponding locking hold on the housing when at least one locking tab is aligned with the corresponding locking hole. In one embodiment, the locking clip can be made of several parts which all together act as a single elastic piece. In one embodiment, the locking clip can be made of a molded polymer such as acrylonitrile butadiene styrene (ABS) or biodegradable thermoplastics. The biodegradable thermoplastics may include biodegradable thermoplastic aliphatic polyester such as polylactic acid or polylactide. In another embodiment, the locking clip is able to absorb at least a tip pinch force of 25 pound-force, but preferably at least about 31 pound-force, before permanently being deformed or lose flexibility.

In one embodiment, the locking clip 1000 may be made of a single piece in the shape of a band that has a straight middle portion 1001, which extends in both directions and curvaturely 1002 turns to about 90 degrees with respect to the straight middle portion 1001 to form an open jaw. The extension in each direction may end with an ridged edge 1003. In one embodiment, two portions of the locking clip may intersect at an acute angle to form the ridged edges 1003. The two portions may come from one single piece, i.e. the locking clip, which may be folded along the ridged edge inward to form the acute angle, and folded back outward leaving a groove 1010 near the ridged edge. Alternatively, and/or additionally, each extension may advantageously have a tail piece 1004 at each end. The tail piece 1004 may ease the folding of the locking clip and forming of the ridged edge 1003 in the fabrication process.

In one embodiment, the locking tabs 1010 may be a raised surface area that extrudes or raises from the locking clip. In one embodiment, the raised surface area can be manufactured by a molding process together with the locking clip. Alternatively, and/or additionally, the locking tabs 1010 can be made of additional pieces of same or different materials and joined to the locking clip by adhesive or other bonding processes.

In one embodiment, the locking clip may be disposed in a flattened position, i.e. the edge of the band is to be touching the insert plate. Alternatively, and/or additionally, the locking clip may have a mounting means for attaching the locking clip to the insert plate. As shown in FIG. 17, the mounting means may include a mounting housing 1006 that has one or more side walls 1011, a mounting plate 1007 joining the one or more side walls. When the locking clip is attached to the insert plate in a flattened position, adhesive can be disposed between the insert plate and the edge of the locking clip band. Additionally and/or alternatively, adhesive can be disposed between the insert plate and the mounting plate. Additionally and alternatively, the mounting plate may have one or more holes 1008, to allow the adhesive to penetrate through the one or more holes on the mounting plate from underneath to achieve a stronger bonding.

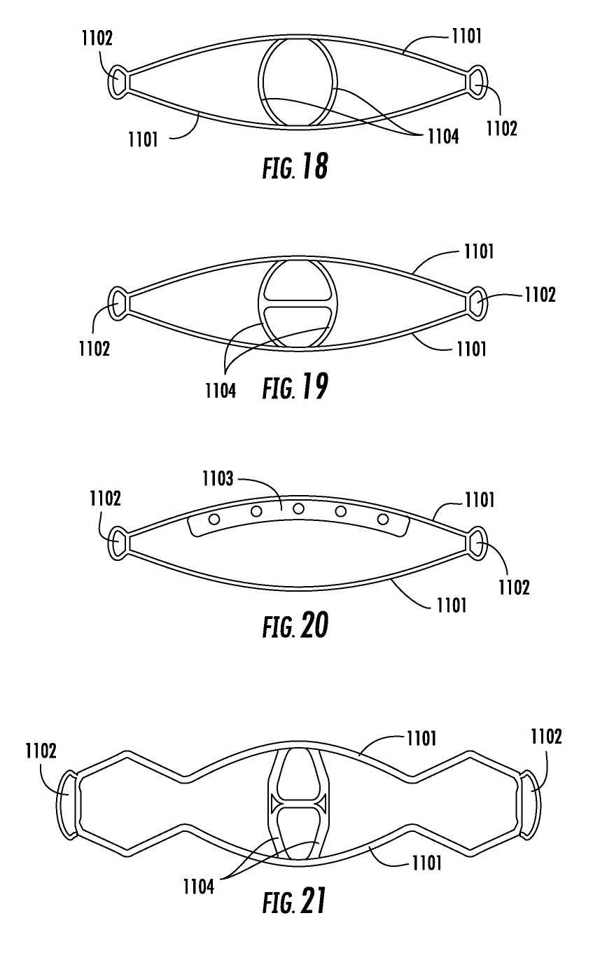

In other embodiments, the locking means may also include variations of locking clip such as those shown in FIGS. 18-22. With reference to FIGS. 18-21, each locking clip has a closed elastic body formed by a pair of two elastic bands 1101, at least a pair of locking tabs 1102. In one embodiment, the two ends where the curved elastic bands join together can be configured to have a dual function and act both as locking tabs and ridged edges, to perform both locking and stopping functions.

Additionally, the elastic body may have an inner tension ring 1104 that can be configured to achieve an optimal tension that is required for an adult to release the locking means by exertion of tip pinch by hand. The locking clip may also have a mounting means (1103 in FIG. 20) that is similar in structure and function to the mounting means shown in FIG. 17.

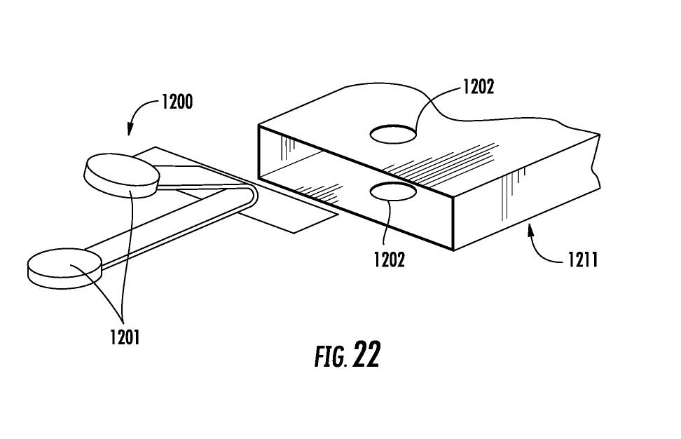

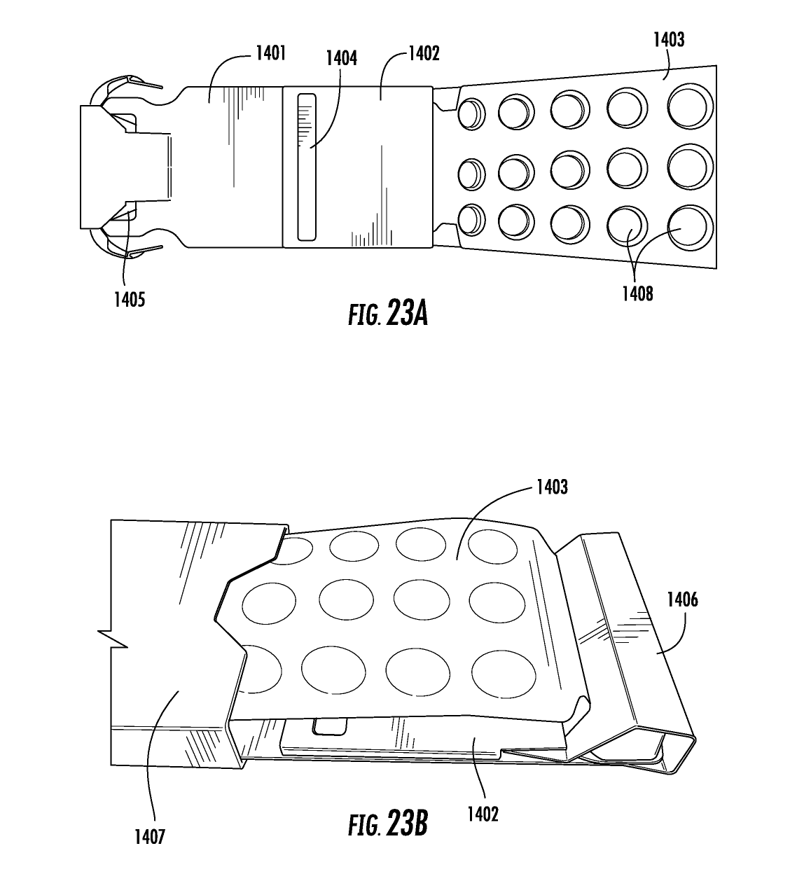

FIG. 22 shows an example of a locking clip 1200 that has two locking tabs 1201. The locking tabs 1201 can be configured to fit into the locking holes 1202 on top and bottom side of the housing 1211. A user needs to press the locking tabs 1201 vertically in order to release the locking means.

With reference to any of the variations of the locking clip shown in FIGS. 17-22, the locking clip can be made of different elastic properties that require different pinching force on the pair of locking tabs for releasing the locking means. Proper pinching force required may be achieved by the material and thickness of the locking clip. For example, in one embodiment, the locking clip can be made of ABS and the thickness can be about 1.6 mm (202 in FIG. 2 or 1000 in FIG. 17). This pinching force requirement may vary depending on different age and gender group of the user by whom the dispensing system is to be used. For example, the average range of tip pinching force for a 6-7 year old male child is 4-10 pound-force for right hand and 5-11 pound-force for left hand; the average range of tip pinching force for a 50-54 year old man is 11-24 pound-force for right hand and 12-26 pound-force for left hand (1 pound-force=4.44822 Newton). In one embodiment, the sufficient tip pinch force required on the pair of locking tabs for releasing the locking means by an adult is at least 45 Newtons regardless of gender. In another embodiment, the sufficient tip pinch force is at least 50 Newtons. In another embodiment, the sufficient tip pinch force is at least 54 Newtons.

When sufficient tip pinch force is exerted by two fingers of one hand of an adult, each of the two locking tabs of the locking clip move inward towards each other at a lateral distance from the position when the insert plate was at the closing position. This lateral distance may be in the range between minimal distance and maximal distance, where the locking means will not be released if the lateral distance is below the minimal, and a higher than maximal distance bears the risk of irreversible deformation and deterioration of the locking clip. In one embodiment, this lateral distance may be at least 1 mm in order for the locking means to be released from the locking hole. In another embodiment, the lateral distance may be in the range of between 1 mm and 20 mm. In another embodiment, the lateral distance may be in the range of between 2 mm and 15 mm. In another embodiment, the lateral distance may be in the range of between 4 mm and 10 mm.

Returning to FIG. 16, a method of recording compliance usage associated with using a unitary dosage dispensing system disclosed in this document may include detecting, by the circuit, an interruption of the sensor network when an opening on the dispenser shell is bursted by the user; time-stamping, by the circuit or micro-processor or processing unit, a time when an instance of the sensor network interruption occurs. Alternatively, and/or additionally, the method may include identifying and recording, by the circuit, which one of the opening is interrupted via the sensor network. As appreciated by a person ordinarily skilled in the art, the method using the disclosed system may also include recording other information about the dispensing history. The method may also include storing various compliance usage information in a memory for later retrieval. Additionally and/or alternatively, the method may also include encoding the compliance usage information and outputting the encoded information such as on a LCD display. In an embodiment, the stored data may contain real-time compliance evaluation of the patient medication intake based on the dispensing history, for example, information about whether the user's usage of the medication complies.

In another aspect, the dispensing system may include a micro-processor or processing unit and a non-transitory computer readable medium storing program instructions. The program instructions can be written in any machine code, high-level programming languages such as C, C# or Java or any script languages. The program instructions may be executed by the micro-processor or processing unit, that will implement various steps of recording compliance usage associated with using the unitary dosage dispensing system disclosed in this document.

As shown in FIGS. 23A-B, the illustrated embodiments of the dispensing system may also have some variations. For example, a dispenser shell 1403 can be attached to the insert plate 1401 at an end opposite to the locking clip 1405. The dispenser shell may similarly have multiple unit dose containers 1408 and a sensor network to detect the open circuit at each instance when a unit dose is dispensed. The insert plate 1401 may have a jacket 1402 that contains therein a circuit that is electrically connected to the sensor network and configured to monitor the dispensing of the pills. The jacket 1402 may also have a cutout 1404 to accommodate a display of the circuit. In one embodiment, the dispenser shell 1403 can be folded onto the insert plate and stowed inside the housing 1407 along with the insert plate.

In one embodiment, the system may have a circuit attached to the insert plate and electrically coupled to the sensor network to detect the open circuit at each instance when a one of the frangible signal paths is interrupted as the unit dose is dispensed. The circuit may record a time at each instance when the unit dose is dispensed, and compute and store a compliance reporting result in a memory for later retrieval. The system may include a display, such as a LCD, a glass or flexible display that is in communication with the circuit and, upon user's push

The above illustrated embodiments provide various advantages in a child resistant and/or senior friendly dispensing system, in that the system can be made primarily with cardboard, plastic or other inexpensive materials yet can be made to effectively prevent a child from opening it by requiring a release-and-pull action that can be easily done by a senior but cannot be easily done by a child.

The above-disclosed features and functions, as well as alternatives, may be combined into many other different systems or applications. For example, in one embodiment, the grip as similarly described in the embodiments in FIGS. 13A-B can be attached to the insert plate in the embodiment shown in FIG. 23B (1406). Alternatively, and/or alternatively, the end of the insert plate and releasing tab 207 as similarly described in the embodiments in FIG. 2 can also be attached to the insert plate in the embodiment shown in FIG. 23B. In another example, a senior friendly system may be adapted to not require a user to exert pinching force while pulling the insert plate simultaneously in order to open. In other words, the system may not need to have a locking function, but instead a stopping means will be sufficient. This can be done by configuring the locking means so that it will not lock the insert plate when it is stowed in the housing in the closing position. In one embodiment, this can be done by eliminating the recess area 701 (in FIG. 14), allowing the locking clip to slide freely inside the housing until it falls into the recess area 702 (in FIG. 14). Various presently unforeseen or unanticipated alternatives, modifications, variations or improvements may be made by those skilled in the art, each of which is also intended to be encompassed by the disclosed embodiments.

1. A senior friendly unitary dose dispensing system comprising:
a) a housing having at least two opposite side walls, an opening side between the two opposite side walls;
b) an insert plate for attaching a plurality of unit dose containers, wherein the insert plate is configured to be stowed in the housing in a closing position and slide out of the housing through the opening side in an opening position;
c) at least one locking means for locking the insert plate to the housing, the locking means comprises a locking clip mounted to one end of the insert plate and is configured to retract upon exertion of sufficient tip pinch force inward so that the insert plate is released from the closing position and slides out of the opening side of the housing in the opening position; and
d) a stopping means disposed inside the housing for limiting outward sliding of said insert plate from the housing when the insert plate is released from the closing position; and
wherein the stopping means comprises an inner lining comprising a cutout configured to block the at least one locking clip from sliding outward when the insert plate is at a desired opening position.

2. The system of claim 1, wherein the housing comprises at least one locking hole on one of the two opposite side walls and the locking clip comprises at least one locking tab that is positioned to:
mate with said at least one locking hole and extend through and outside of the locking hole when the insert plate is stowed in the housing in the closing position; and
allow the tip pinch force to be exerted upon the locking clip through said locking hole of the housing.

3. The system of claim 1, further comprising:
a dispenser shell removably attached to the insert plate, wherein the dispenser shell has a face and defines the plurality of unit dose containers, each container defining an opening through the dispenser face.

4. The system of claim 3, further comprising a retainer sheet configured to be confrontingly affixed to the dispenser shell face to seal each container opening and to burst proximate to each opening as the unit dose is dispensed through the respective openings of the containers.

5. The system of claim 1, wherein the insert plate further comprises a releasing tab at an end opposing to the locking clip, wherein the releasing tab is positioned to:
be flush with the opening side of the housing when the insert plate is in the closing position; and
release the insert plate from the closing position and slide the insert plate out of the opening side of the housing only when the locking clip is pinched inward simultaneously.

6. The system of claim 1, wherein:
the insert plate further comprises a grip at an end opposing to the locking clip for stabilizing the insert plate in the housing when at the closing position; and
the housing further comprises a top and bottom wall, at least one of which have a cutout at an end proximate to the opening side, wherein the cutout is positioned to cause at least a portion of the grip to be exposed through the cutout when the insert plate is in the closing position so that the grip can be gripped near the cutout to release the insert plate from the closing position and slide out of the opening side.

7. The system of claim 1, wherein the locking means further comprises an inner lining disposed inside the housing, the inner lining comprising an edge configured to block the at least one locking clip from sliding when the insert plate is at the closing position.

8. (canceled)

9. (canceled)

10. The system of claim 4, wherein the retainer sheet is made of, paper, or cardboard or thin plastic film.

11. The system of claim 4, further comprising:
a sensor network arranged about the retainer sheet to have a plurality of frangible electrical container integrity signal paths, each path being positioned to substantially extend across a respective opening when the retainer sheet is affixed onto the dispenser shell face;
a circuit attached to the insert plate and electrically coupled to the sensor network and configured to record a time at each instance when a one of the frangible signal paths is interrupted as the unit dose is dispensed, the circuit being further adapted to compute and record information related to one or more dispensings of the unit dose; and
a display attached to the insert plate and in communication with the circuit and configured to output the dispensing related information or a compliance code pertaining to the one or more dispensings of the unit dose.

12. The system of claim 11, further comprising a substrate disposed between the sensor network and the retainer sheet.

13. The system of claim 12, wherein the substrate is made of metal, aluminum, copper, paper, or cardboard or thin plastic film.

14. The system of claim 11, wherein the circuit is connected to the sensor network via anisotropic conductive film (ACF)/adhesive bonding, conductive adhesive glue, laser welding or conductive adhesive gel.

15. The system of claim 11, wherein the circuit and the sensor network are made of a single layer, wherein the single layer is of made from etched metal or a functional printing process.

16. The system of claim 15, wherein said etched metal layer is made of aluminum, copper or conductive metals.

17. The system of claim 11, wherein the display is a glass or flexible or LED display.

18. A child resistant senior friendly dispensing system, comprising:
a) a housing having at least two opposite side walls, an opening side between the two opposite side walls and a first and second locking hole, each on one of the two opposite side walls;
b) an insert plate for attaching a plurality of unit dose containers, wherein the insert plate is configured to be stowed in the housing in a closing position and slide out of the housing through the opening side in an opening position; and
c) at least one locking means for locking the insert plate to the housing, the locking means comprising a locking clip mounted to an end of the insert plate and having a first and second locking tab, each locking tab being configured to:
(i) mate with one of the first and second locking holes, respectively, and extend through and outside of the locking hole when the insert plate is stowed in the housing in the closing position, and
(ii) retract, upon exertion of sufficient tip pinch force, through said locking hole so that the insert plate is released from the closing position and slides out of the opening side of the housing in the opening position;
the system further comprising a stopping means disposed inside the housing for limiting outward sliding of said insert plate from the housing when the insert plate is released from the closing position; and wherein the stopping means comprises an inner lining comprising a first and second cutouts configured to stop the locking clip from sliding outward when the insert plate is at a desired opening position.

19. The system of claim 18, further comprising a dispenser shell removably attached to the insert plate, wherein the dispenser shell has a face and defines the plurality of unit dose containers, each container defining an opening through the dispenser shell face.

20. The system of claim 19, further comprising a retainer sheet configured to be confrontingly affixed to the dispenser shell face to seal each container opening and to burst proximate to each opening as the unit dose is dispensed through the respective openings of the containers.

21. The system of claim 18, wherein the insert plate further comprises a releasing tab at an end opposing to the locking clip, wherein the releasing tab is positioned to:
be flush with the opening side of the housing when the insert plate is in the closing position; and
configured to release the insert plate from the closing position and slide the insert plate out of the opening side of the housing only when at least the first and second locking tabs are pushed in simultaneously.

22. The system of claim 18, wherein:
the insert plate further comprises a grip at an end opposing to the locking clip for stabilizing the insert plate in the housing when at the closing position; and
the housing further comprises a top and bottom wall, at least one of which has a cutout at an end proximate to the opening side, wherein the cutout is positioned to cause at least a portion of the grip to be exposed through the cutout when the insert plate is in the closing position so that the grip can be gripped near the cutout to release the insert plate from the closing position and slide out of the opening side, and
a display attached to the insert plate and in communication with the circuit and configured to display the related information or a compliance code pertaining to the one or more dispensings of the unit dose.

23. The system of claim 18, wherein the locking means further comprises an inner lining disposed inside the housing, the inner lining comprising one or two edges configured to block the locking clip from sliding when the insert plate is at the closing position.

24. (canceled)

25. (canceled)

26. (canceled)

27. The system of claim 18, wherein each of the first and second locking holes is located at a longitudinal distance from the opening side of the housing, wherein the distance is at a range between about 75% and 100% of the longitudinal length of the first or second side wall.

28. The system of claim 27, wherein the distance is between 90% and 99% of the longitudinal length of each corresponding side wall and wherein the lateral distance between the first and second locking holes is between 30 and 90 millimeters.

29. The system of claim 18, wherein the lateral distance between the first and second locking holes is between 64 and 88 millimeters, between 72 and 80 millimeters, or between 30 and 90 millimeters.

30. (canceled)

31. (canceled)

32. The system of claim 18, wherein each of the first and second locking tabs has a surface in a shape of circular, parallelipidic, triangles, ovals, rectangles, arrows, squares, trapezium, parallelograms, pentagons or hexagons.

33. The system of claim 32, wherein the surface of each of the first and second locking tabs has an area in the range between 20 mm² and 30 mm².

34. The system of claim 18, wherein each of the first and second locking tabs has a surface area between 75% and 99.9% of an area of the locking hole on the first or second side wall of the housing.

35. The system of claim 18, wherein the locking clip is made of a single elastic piece.

36. The system of claim 18, wherein the locking clip is made of material selected from acrylonitrile butadiene styrene (ABS) or biodegradable thermoplastics.

37. The system of claim 18, wherein the locking clip comprises a mounting means for attaching the locking clip to the insert plate.

38. The system of claim 37, wherein the mounting means comprises a mounting housing having one or more side walls, a mounting plate joining the one or more side walls, wherein the mounting plate defines one or more holes.

39. The system of claim 38, wherein the locking clip is attached to the insert plate with an adhesive disposed between the insert plate and the mounting plate, wherein the adhesive penetrates through the one or more holes on the mounting plate.

40. A method of resisting children's access to a dispensing system according to claim 1,
the method comprising:
exerting sufficient tip pinch force with two finger of a hand on the locking clip inward simultaneously; and
pulling out the releasing tab with another hand simultaneously to slide the insert plate outward through the opening side of the housing,
wherein the sufficient tip pinch force is of at least 45 Newtons, at least 50 Newtons or at least 54 Newtons.

41. (canceled)

42. (canceled)

43. (canceled)

44. The method of claim 40, wherein the sufficient force causes each of the first and second locking tabs to move inward at a lateral distance from a position when the insert plate was at the closing position.

45. The method of claim 44, wherein the lateral distance caused by the sufficient force is at the range selected from the group consisting of between 1 mm and 20 mm; between 2 mm and 15 mm, and between 4 mm and 10 mm.

46. (canceled)

47. (canceled)

48. A method of recording compliance usage associated with using a unitary dosage dispensing system according to claim 1, the method comprising:
detecting, by a circuit, an interruption of the sensor network when an opening on the dispenser shell is bursted by a user;
recording, by the circuit, compliance usage information about dispensing that includes at least a timestamp of when an instance of the sensor network interruption occurs;
storing in a memory, by the circuit, the compliance usage information; and
outputting, by the circuit, the compliance usage information on the display upon receiving a user request;
wherein outputting the compliance usage information further comprises: encoding, by the circuit, the compliance usage information; and outputting, by the circuit, the encoded compliance usage information on the display.

49. (canceled)

50. (canceled)

51. (canceled)
